(19) United States
(12) Patent Application Publication
(10) Pub. No.: US 2004/0131206 A1
(43) Pub. Date: Jul. 8, 2004

(54) User selectable sound enhancement feature

(76) Inventors: James Cao, Vancouver (CA); Stephen George Kropp, Surrey (CA); Jagjit S. Grewal, Surrey (CA); Nader Hodali, Coquitlam (CA)

Correspondence Address: SHAW PITTMAN, IP GROUP, 1650 TYSONS BOULEVARD, SUITE 1300, MCLEAN, VA, 22102, US

(21) Appl. No.: 10/338,474

(22) Filed: Jan. 8, 2003

(51) Int. Cl. H03G 5/00

(52) U.S. Cl. 381/103; 381/98

(57) ABSTRACT

A method and apparatus for providing a user-selectable sound profile for a telecommunications device, wherein the user may select at least one available frequency response profile to be applied to an audio signal by a digital equalizer.

### BACKGROUND OF THE INVENTION

1. Field of the Invention

This invention relates generally to electronic communications devices and particularly to a telecommunications device having a selectable frequency response for audio output.

2. Background Art

Telecommunications devices are well known in the art and include wireless radios, cellular telephones, cordless telephones, and standard telephones. These devices typically encode audio signals into electrical signals, and transmit those signals over a communications medium, such as a telephone line or a wireless network. At the receiving end of the transmission, the received signals are converted back into audio signals, and fed to the user's ear via a speaker.

In certain circumstances, users may have difficulty hearing the audio signal being fed through the speaker. For example, if the telephone earpiece does not seal well with the user's ear, the low-frequency components of the audio signal will be attenuated, making conversation difficult to understand. The ambient noise of the user's environment may also make it difficult for the user to hear the audio signal. Likewise, the user may have a hearing disability or use a hearing aid. When any of the above problems arise, the user generally responds by adjusting the volume. Unfortunately, simply adjusting the volume does not necessarily address the problem. Many sources of attenuation or ambient noise are limited to a sub-band of the entire spectrum of audible sound. For example, for telephones, the spectrum of audible sound is typically 300 Hz to 4 kHz. A poor seal between the telephone earpiece and the user's ear, however, typically attenuates only those frequency components below 1 kHz. If the user simply increases the volume in response to this attenuation, the high-frequency sounds will become too loud, while the low frequency sounds become just audible. Thus, the user may now hear the low frequency sounds, but at the painful expense of having too-loud high-frequency sounds pumped into the user's ear. Some manufacturers have attempted to solve this problem by manufacturing “low acoustic impedance” or “leak tolerant” telephone receivers. These receivers generally include resonant chambers in the receiver chassis which reduce the attenuation of low-frequency signals. Other mechanical solutions to this problem have been proposed, such as the adjustable headset disclosed in U.S. Pat. No. 5,729,605. However, such mechanical solutions are cumbersome to manufacture and difficult to precisely tune.

Thus, it would be advantageous to provide the user with a selectable digital audio equalizer to compensate for this type of frequency-dependent attenuation. Such digital audio equalizers are well known in the field of home audio equipment, such as stereo equipment. Digital Signal Processors (DSPs) which can function as equalizers are also known in the art, such as Texas Instruments' TLC320AD81C Stereo Audio Digital Equalizer DAC.

Telecommunications devices are also required to meet certain telecommunications standards, such as TIA 470B, TIA 470C, and FCC Part 68.316 HAC. Because telecommunications devices generally only have a single, fixed frequency response for audio output, they must be carefully engineered such that the output frequency response meets all of these standards. The result is often a frequency response which is satisfactory for all three standards, but is less than ideal for any one standard. For example, FCC Part 68.316 HAC (Hearing Aid Compatibility) specifies an inductive frequency response, while TIA standards focus on audible frequency response. A single device that meets both of these standards simultaneously will often perform poorly; however, an improvement could be realized by providing a device with a variable frequency response—one which can be adjusted to meet the requirements of a particular standard as needed. Accordingly, it would also be desirable if a user-selectable equalizer produced a separate frequency response for audio output for each one of the above standards.

### SUMMARY OF THE INVENTION

The objects and advantages of the present invention are achieved by providing a cordless telephone or other telecommunications device with a digital audio equalizer. The digital audio equalizer applies an audio frequency profile to the received audio signal, thereby attenuating some frequencies and/or amplifying others.

The digital audio equalizer may be capable of applying more than one audio frequency profile to the received audio signal. For example, the equalizer may have one profile for amplifying the bass components of a signal, and a second profile for amplifying the treble components of a signal. The user may select, via buttons on the cordless telephone, for example, which audio profile the user prefers. In this manner the user may select an audio profile which best matches the user's hearing spectrum.

The digital audio equalizer may also be capable of applying particular profiles in order to meet particular telecommunications or industry standards.

These and other desirable characteristics of the present invention will become apparent in view of the present specification and drawings.

### BRIEF DESCRIPTION OF THE DRAWINGS

For a better understanding of the present invention, reference may be had to the accompanying drawings in which:

FIG. 1 illustrates a cordless telephone system according to the present invention.

FIG. 2 illustrates several possible audio frequency response filters which may be applied to an audio signal in accordance with the present invention.

FIG. 3 illustrates a block diagram view of the cordless telephone handset of FIG. 1.

FIG. 4 illustrates a partial top plan view of the cordless telephone handset of FIG. 1.

FIG. 5 illustrates the frequency response of a cordless telephone handset according to the present invention.

### DETAILED DESCRIPTION

While this invention is susceptible of embodiment in many different forms, there are shown in the drawings and will be described in detail, a preferred embodiment, with the understanding that the present disclosure is to be considered as an exemplification of the principles of the invention and is not intended to limit the invention to the embodiments illustrated.

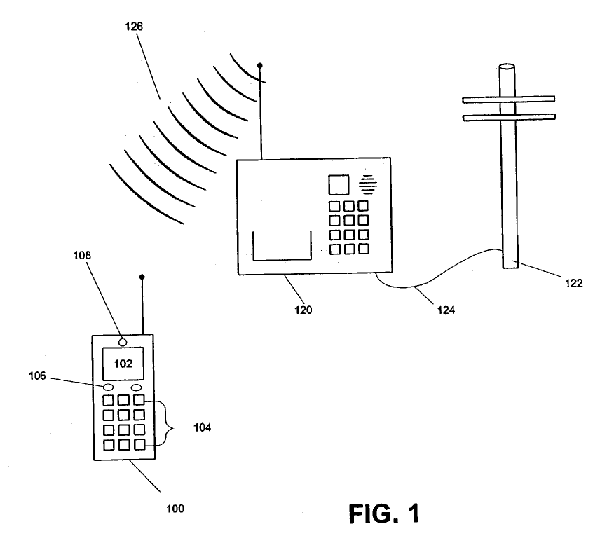

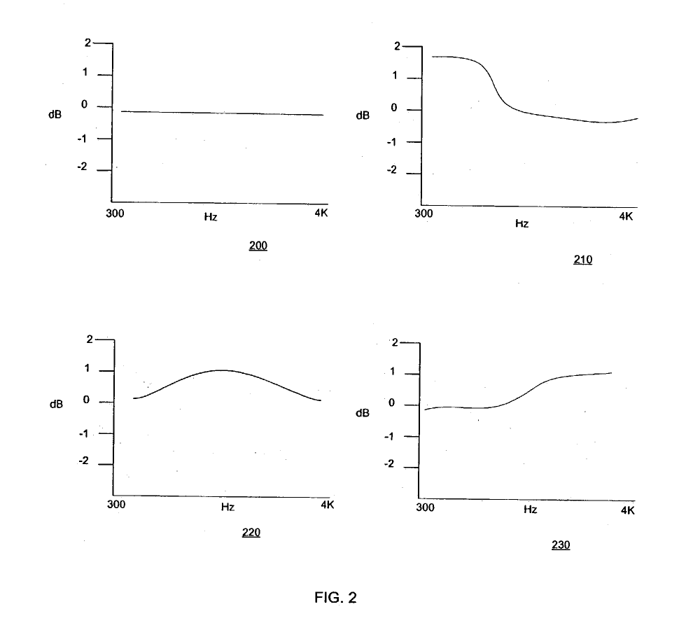

FIG. 1 illustrates a cordless telephone system as is well known in the art. Specifically, FIG. 1. illustrates cordless telephone handset 100 and cordless telephone base 120. Cordless telephone handset 100 has LCD screen 102, keypad 104, audio profile select button 106 and speaker 108. Audio profile select button 106 is a “soft” function key which, when depressed, allows the user to cycle through four audio profiles, shown in FIG. 2: Normal (or natural) 200, Bass Boost 210, Mid Boost 220 and Treble Boost 230. Particularly, when audio profile select button 106 is pressed a first time, LCD 102 displays the current audio profile. By default, the current audio profile will usually be Normal. When the user again depresses audio profile select button 106, LCD 102 displays the next audio profile, and the phone's audio profile changes to “bass boost,” as described below. In this manner, the user can quickly select an audio frequency response profile that suits the user's needs.

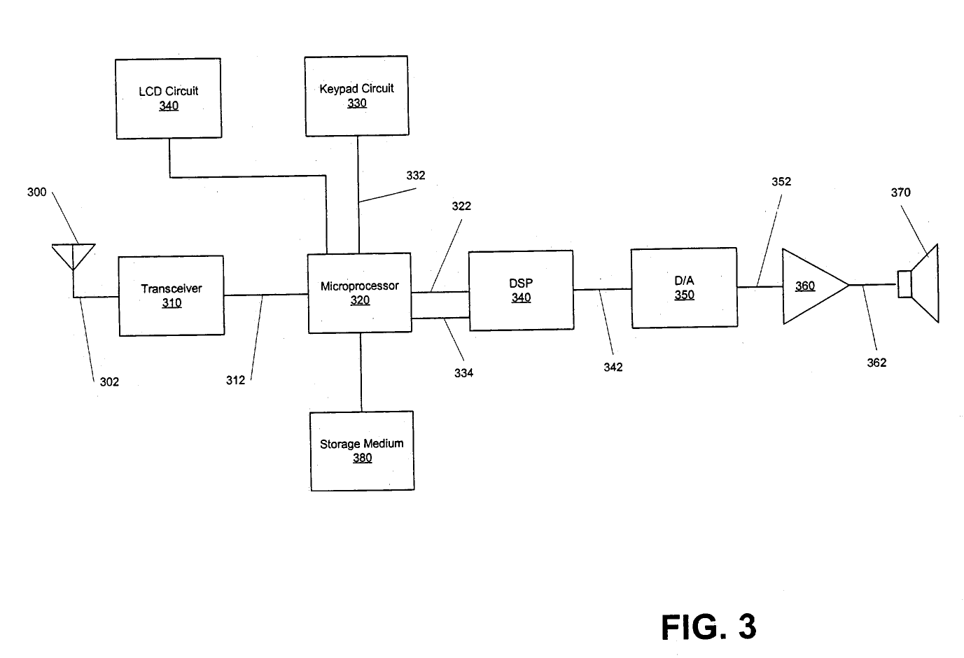

Cordless telephone base 120 is connected to communications network 122. Cordless telephone base 120 receives communication signals 124 from communications network 122, generally the public switched telephone network (PSTN). Cordless telephone base 120 converts communications signals 124 to RF communications signals 126 and transmits RF communications signals 126 to cordless telephone handset 100. Cordless telephone handset 100 receives RF communications signals 126 and converts those signals into audio information, which is communicated to the user via speaker 108. The process by which RF communications signals 126 are converted into audio signals is described in more detail in connection with FIG. 3.

FIG. 3 shows antenna 300, which receives RF signal 302. RF signal 302 is fed to transceiver 310, which demodulates received RF signal 302 into received data signal 312. Received data signal 312 is then fed to microprocessor 320. Microprocessor 320 extracts received audio signal 322 from received data signal 312 and feeds received audio signal 322 to DSP 340. DSP 340 functions, at least in part, as a digital audio equalizer which can attenuate or amplify specified sub-bands of an audio signal. DSP 340 receives instructions in the form of a set of parameters, which define the frequency sub-bands to be altered and the attenuation or amplification to be applied to those respective sub-bands, and which are received via control signal 334. DSP 340 is preferably a Digital Signal Processor manufactured specifically for serving as an equalizer for audio signals. However, those skilled in the art will recognize that other equalizing means may be used without departing from the scope of the present invention. For example, DSP 340 may instead be a general-purpose microprocessor or a switched network of filter circuits.

Microprocessor 320 also receives audio profile selection signal 332 from keypad circuit 330. Keypad circuit 330 includes audio profile select button 106 (shown in FIG. 1). Audio profile selection signal 332 indicates whether the user has depressed audio profile select button 106.

Microprocessor 320 is further connected to storage medium 380. Storage medium 380 is a form of electronically erasable memory, in which microprocessor 320 stores a variety of operating information. For each audio profile, microprocessor 320 stores a set of parameters in a known location in storage medium 380.

Microprocessor 320 is additionally connected to LCD circuit 390, which in turn controls LCD 102 (shown in FIG. 1).

When the user depresses audio profile select button 106 (shown in FIG. 1), microprocessor 320 receives audio profile select signal 332. Microprocessor 320 then signals LCD circuit 390 to display the name of the current audio profile—for example, “Normal.” When the user again depresses audio profile select button 106, microprocessor 320 reads the parameters for the next audio profile from storage medium 380 and feeds the audio profile parameters to DSP 340 via control signal 334. Microprocessor 320 then displays the name of the newly selected audio profile via LCD circuit 390.

When DSP 340 receives new audio profile parameters via control signal 334, it alters received audio signal 322 in the frequency domain according to the selected audio profile. For example, if the selected profile is Bass Boost 202, DSP 340 will alter incoming data signal 322 by increasing the amplitude of the low frequency components of the signal. DSP 340 continues to apply this audio profile to audio signal 322 until a new set of parameters is received via control signal 334. Equalized audio signal 342 is then fed to D/A converter 350. D/A converter 350 outputs analog audio signal 352 to amplifier 360, which in turn feeds amplified audio signal 362 to speaker 370.

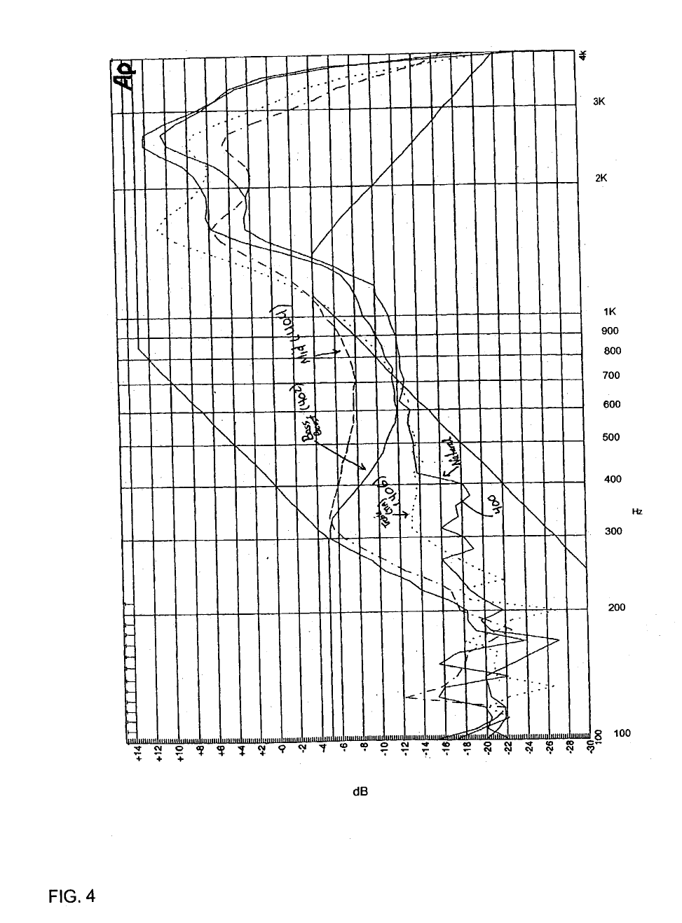

FIG. 4 illustrates some of the frequency responses obtained from a cordless telephone handset using the technique described above. The frequency responses shown are measured acoustically at the speaker output of a cordless telephone handset. Line 400 shows the output with the “Normal” frequency response profile applied to the signal. In other words, line 400 illustrates the frequency response of the cordless telephone handset that subjectively sounds normal. Line 402 illustrates the frequency response of the cordless telephone handset with the Bass Boost profile applied to the audio signal. Line 404 illustrates the frequency response of the cordless telephone handset with the Mid Boost applied. Likewise, Line 406 illustrates the frequency response of the cordless telephone handset with the Treble Boost applied.

It will be appreciated by those skilled in the art that the present invention is not limited to the audio profiles illustrated. Rather, those skilled in the art will readily understand from this disclosure that each cordless telephone handset design will have its own unique natural frequency response and hence different audio profiles will be required to achieve the desired results.

It will be further appreciated by those skilled in the art that the individual audio profiles can be adjusted to provide an output frequency response that complies with telecommunications or industry standards, such as TIA 470B. In addition, each individual frequency profile may be adapted to comply with a particular industry standard. For example, profile 200 could be adapted so that the output of the cordless telephone handset complies with TIA 470B, profile 210 could be adapted so that the output of the cordless telephone handset complies with TIA 470C, and profile 220 could be adapted so that the output of the cordless telephone complies with FCC Part 68.316 HAC. In this manner the user is provided with a telecommunications device that complies with each standard individually while providing superior sound quality.

In addition, it can be appreciated by those skilled in the art that the invention is not limited to the particular components illustrated. For example, the audio profile parameters may be stored on DSP 240 itself, rather than in storage medium 208. DSP 240 may also be combined with other devices, such as D/A converter 250 or amplifier 260. Furthermore, if numerous frequency response profiles are to be made available, multiple DSPs may be required, or a DSP may be combined with a switchable filter circuit.

Moreover, the audio profile select button 106 may also take other forms without departing from the scope of the invention. For example, cordless telephone handset 100 may simply include soft function keys, where the user selects the desired audio profile from among an hierarchy of menus. Numerous other selection means are known in the art and need not be discussed here.

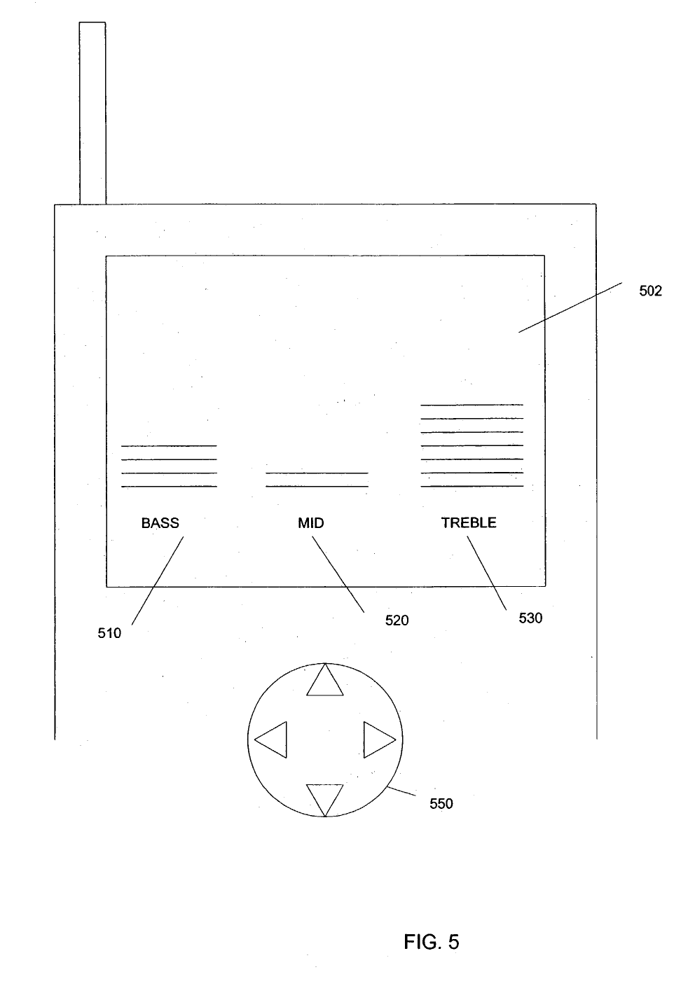

It is also not necessary that the frequency response profiles be fixed permanently in memory. Rather, the telephone could have a user-adjustable frequency response, wherein the user may select the amplification and/or attenuation for a particular sub-band, as illustrated in FIG. 5. Particularly, LCD 502 displays “Bass” Column 510, “Mid” Column 520 and “Treble” Column 530. The user may switch between columns and adjust their values via directional pad 550. The user-selected values are then stored in memory and applied to the audio signal. Of course, a device in accordance with the present invention may store any combination of user-defined and pre-defined profiles.

The foregoing description and drawings merely explain and illustrate the invention and the invention is not limited thereto, as those skilled in the art who have the disclosure before them will be able to make modifications and variations therein without departing from the scope of the invention.

What is claimed as new and desired to be secured by Letters Patent is:

1. A telecommunications device comprising:
a receiver for receiving a telecommunications signal;
a processor for converting the telecommunications signal into an audio signal;
a storage medium for storing at least one frequency response profile;
selection means for selecting the at least one frequency response profile;
equalizer means for applying the at least one frequency response profile to the audio signal to produce an equalized audio signal; and
a speaker for playing back the equalized audio signal.

2. The telecommunications device of claim 1 wherein the telecommunications device is a cordless telephone.

3. The telecommunications device of claim 1 wherein the telecommunications device is a handsfree speakerphone.

4. The telecommunications device of claim 1 wherein the at least one frequency response profile produces an equalized audio signal that complies with one of: TIA 470B, TIA 470C, and FCC Part 68.316 HAC.

5. The telecommunications device of claim 1 wherein the telecommunications device further comprises audio profile adjustment means by which the user may adjust the frequency response profile characteristics.

6. A method for adjusting the audible frequency response of a telecommunications device, comprising the steps of:
receiving a signal;
extracting an audio signal from the received signal;
providing parameter defining at least one frequency response profile stored in a storage medium;
selecting one of the at least one frequency response profiles to be applied to the audio signal;
applying the selected frequency response profile to the audio signal to produce an equalized audio signal; and
playing the equalized audio signal through a speaker.

7. The method of claim 6 wherein the step of providing parameter defining at least one frequency response profile stored in a storage medium further comprises the step of providing a Bass Boost profile, a Treble Boost profile, a Mid Boost profile and a Natural Boost profile.

8. The method of claim 6 wherein the equalized audio signal complies with one of: TIA 470B, TIA 470C and FCC Part 68.316 HAC.

9. The method of claim 6 wherein the equalized audio signal complies with a recognized telecommunication standard.

10. A telecommunications device comprising:
a telephone line interface means for receiving a telecommunications signal;
a processor to control the routing of the telecommunications signal;
a storage medium for storing at least one frequency response profile;
selection means for selecting the at least one frequency response profile;
equalizer means for dynamically applying a frequency response profile to the audio signal to produce an equalized audio signal; and
a speaker for playing back the equalized audio signal.
